(19) United States
(12) Patent Application Publication
(10) Pub. No.: US 2024/0260334 A1
(43) Pub. Date: Aug. 1, 2024

(54) ELECTRONIC DEVICE

(71) Applicant: Innolux Corporation, Miaoli County (TW)

(72) Inventors: Ming-Jou Tai, Miaoli County (TW); Chia-Hao Tsai, Miaoli County (TW); Wei-Yen Chiu, Miaoli County (TW)

(73) Assignee: Innolux Corporation, Miaoli County (TW)

(21) Appl. No.: 18/404,903

(22) Filed: Jan. 5, 2024

(30) Foreign Application Priority Data
Feb. 1, 2023 (TW) 112103393

(51) Int. Cl. H10K 59/123; H10K 59/124; H10K 59/131; H10K 59/80

(52) U.S. Cl. CPC H10K 59/123; H10K 59/124; H10K 59/131; H10K 59/8792

(57) ABSTRACT

An electronic device includes a substrate, a thin film transistor, a first organic layer, a first transparent electrode, a second organic layer, and a second transparent electrode. The thin film transistor is disposed on the substrate. The first organic layer is disposed on the thin film transistor and has a hole. The first transparent electrode is disposed on the first organic layer and is at least partially disposed in the hole to be electrically connected to the thin film transistor through the hole. The second organic layer is disposed on the first transparent electrode and is at least partially disposed in the hole. The second transparent electrode is disposed on the second organic layer and is electrically connected to the first transparent electrode. The first transparent electrode and the second transparent electrode respectively have a first width and a second width in a first direction, and the first width is less than the second width.

### CROSS-REFERENCE TO RELATED APPLICATION

This application claims the priority benefit of Taiwan application serial no. 112103393, filed on Feb. 1, 2023. The entirety of the above-mentioned patent application is hereby incorporated by reference herein and made a part of this specification.

### BACKGROUND

### Technical Field

The disclosure relates to an electronic device.

### Description of Related Art

In existing electronic devices (such as display devices), due to the limitation of pixel size, it is difficult to increase the penetration rate and the storage capacitance of pixels, resulting in a decrease in the display quality.

### SUMMARY

The disclosure provides an electronic device, which helps to improve the display quality.

In an embodiment of the disclosure, an electronic device includes a substrate, a thin film transistor, a first organic layer, a first transparent electrode, a second organic layer, and a second transparent electrode. The thin film transistor is disposed on the substrate. The first organic layer is disposed on the thin film transistor and has a hole. The first transparent electrode is disposed on the first organic layer and is at least partially disposed in the hole. The first transparent electrode is electrically connected to the thin film transistor through the hole. The second organic layer is disposed on the first transparent electrode and is at least partially disposed in the hole. The second transparent electrode is disposed on the second organic layer and is electrically connected to the first transparent electrode. The first transparent electrode and the second transparent electrode respectively have a first width and a second width in a first direction, and the first width is less than the second width.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A to FIG. 1D are schematic partial top views of an electronic device according to a first embodiment of the disclosure.

FIG. 2 is a schematic cross-sectional view corresponding to a section line A-A′ of FIG. 1A to FIG. 1D.

FIG. 3A is a schematic partial top view of an electronic device according to a second embodiment of the disclosure.

FIG. 3B is a schematic cross-sectional view corresponding to a section line B-B′ of FIG. 3A.

FIG. 4 is a schematic partial top view of an electronic device according to a third embodiment of the disclosure.

FIG. 5 is a schematic partial cross-sectional view of an electronic device according to a fourth embodiment of the disclosure.

FIG. 6 is a schematic partial cross-sectional view of an electronic device according to a fifth embodiment of the disclosure.

### DESCRIPTION OF THE EMBODIMENTS

Reference will now be made in detail to the exemplary embodiments of the disclosure, and examples of the exemplary embodiments are illustrated in the accompanying drawings. Wherever possible, the same reference numerals are used in the drawings and descriptions to refer to the same or similar parts.

Throughout the disclosure, certain terms are used to refer to specific elements in the specification and the claims. Those skilled in the art should understand that electronic device manufacturers may refer to the same components by different names. The present specification does not intend to distinguish between components that have the same function but different names. In the following specification and claims, words such as “containing” and “including” are open-ended words, so they should be interpreted as meaning “containing/including but not limited to . . . . ”

In the present specification, wordings used to indicate direction, such as “up,” “down,” “front,” “back,” “left,” and “right,” merely refer to directions in the drawings. Therefore, the directional terms are used to illustrate and are not intended to limit the disclosure. In the drawings, the figures depict typical features of the methods, structures, and/or materials used in the particular embodiments. However, the figures are not to be interpreted as defining or limiting the scope or nature of the embodiments. For example, the relative size, thickness, and location of layers, regions, and/or structures may be reduced or enlarged for clarity.

A structure (or layer, element, substrate) described in the disclosure as located on/over another structure (or layer, element, substrate) may mean that the two structures are adjacent and directly connected, or that the two structures are adjacent but not directly connected. Indirect connection means that there is at least one intermediate structure (or intermediate layer, intermediate element, intermediate substrate, intermediate space) between the two structures, and a lower surface of one structure is adjacent to or directly connected to an upper surface of the intermediate structure, while an upper surface of the other structure is adjacent to or directly connected to a lower surface of the intermediate structure. The intermediary structure may be composed of a single-layer or multi-layer physical structure or a non-physical structure and is without limitation. In the disclosure, when a certain structure is set “on” other structures, it may mean that the structure is “directly” on the other structures, or that the structure is “indirectly” on the other structures, that is, at least one structure being also interposed between the structure and the other structures.

The terms “about,” “equal to,” “equivalent” or “same,” “substantially” or “roughly” are generally interpreted as being within 20% of a given value or range, or interpreted as within 10%, 5%, 3%, 2%, 1%, or 0.5% of a value or range. In addition, the term “a given range is from a first value to a second value” or “a given range is within a range from a first value to a second value” mean that the given range includes the first value, the second value, and other values in between.

The ordinal number used in the specification and the claims such as “first” or “second” is used to modify elements, and the ordinal numbers do not imply and represent that the element(s) have any previous ordinal numbers, nor do they represent the order of a certain element and another element or the order of a manufacturing method. The use of the ordinal numbers is only used to clearly distinguish between an element with a certain name and another element with the same name. The claims and the specification may not use the same terms, whereby a first member in the specification may be a second member in the claims.

The electrical connection or coupling described in the disclosure may refer to direct connection or indirect connection. In the case of direct electrical connection, endpoints of elements on two circuits are directly connected or connected to each other by a conductor segment, while in the case of indirect electrical connection, there is a switch, a diode, a capacitor, an inductor, a resistor, other suitable elements, or a combination of the above elements between the endpoints of the elements on the two circuits, but the disclosure is not limited thereto.

In the disclosure, the measurement manner of thickness, length, and width may adopt an optical microscope (OM), and the thickness or the width may be measured by a cross-sectional image in an electron microscope, but the disclosure is not limited thereto. In addition, there may be a certain error between any two values or directions for comparison. In addition, the terms “equal to,” “equivalent,” “same,” “substantially” or “roughly” are generally interpreted as being within 10% of a given value or range. In addition, the term “a given range is from a first value to a second value,” “a given range is within a range from a first value to a second value,” or “a given range is between a first value and a second value” mean that the given range includes the first value, the second value, and other values in between. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

It should be noted that in the following embodiments, the features of several different embodiments may be replaced, recombined, and mixed to complete other embodiments without departing from the spirit of the disclosure. As long as the features of the embodiments do not violate the spirit of the disclosure or conflict with each other, the features may be arbitrarily mixed and matched for use.

Unless otherwise defined, all terms (including technical and scientific terms) used herein have the same meaning as commonly understood by persons skilled in the art to which the disclosure belongs. It may be understood that these terms, such as the terms defined in commonly used dictionaries, should be interpreted as having meanings consistent with the relevant art and the background or the context of the disclosure, and should not be interpreted in an idealized or overly formal manner, unless otherwise defined in the embodiments of the disclosure.

An electronic device of the disclosure may include, for example, a display device, a light emitting device, an antenna device, a sensing device, a splicing device, a touch electronic device, a curved electronic device, or a non-rectangular electronic device, but the disclosure is not limited thereto. The electronic device may be a bendable or flexible electronic device. The display device may be a non-self-illuminating display device or a self-illuminating display device. The electronic device may include, for example, a liquid crystal, a light emitting diode, a fluorescence, a phosphor, a quantum dot (QD), other suitable display media, or a combination of the above. The antenna device may include a frequency selective surface (FSS), a radio frequency filter (RF-Filter), a polarizer, a resonator, or an antenna. The antenna may be a liquid crystal type antenna or a non-liquid crystal type antenna. The sensing device may be a sensing device for sensing capacitance, light, heat, or ultrasonic, but the disclosure is not limited thereto. In the disclosure, an electronic device may include an electronic element, and the electronic element may include a passive element and an active element, such as capacitors, resistors, inductors, diodes, or transistors. The diode may include a light emitting diode or a photodiode. The light emitting diode may include, for example, an organic light emitting diode (OLED), a submillimeter light emitting diode (mini LED), a micro light emitting diode (micro LED), or a quantum dot light emitting diode (quantum dot LED), but the disclosure is not limited thereto. The splicing device may be, for example, a display splicing device or an antenna splicing device, but the disclosure is not limited thereto. It should be noted that the electronic device may be any permutation and combination of the above, but the disclosure is not limited thereto. In addition, the shape of the electronic device may be rectangular, circular, polygonal, a shape with curved edges, or other suitable shapes. The electronic device may have a peripheral system such as a driving system, a control system, and a light source system to support the display device, the antenna device, the wearable device (such as the augmented reality or the virtual reality included), the vehicle-mounted device (such as the car windshield included), or the splicing device.

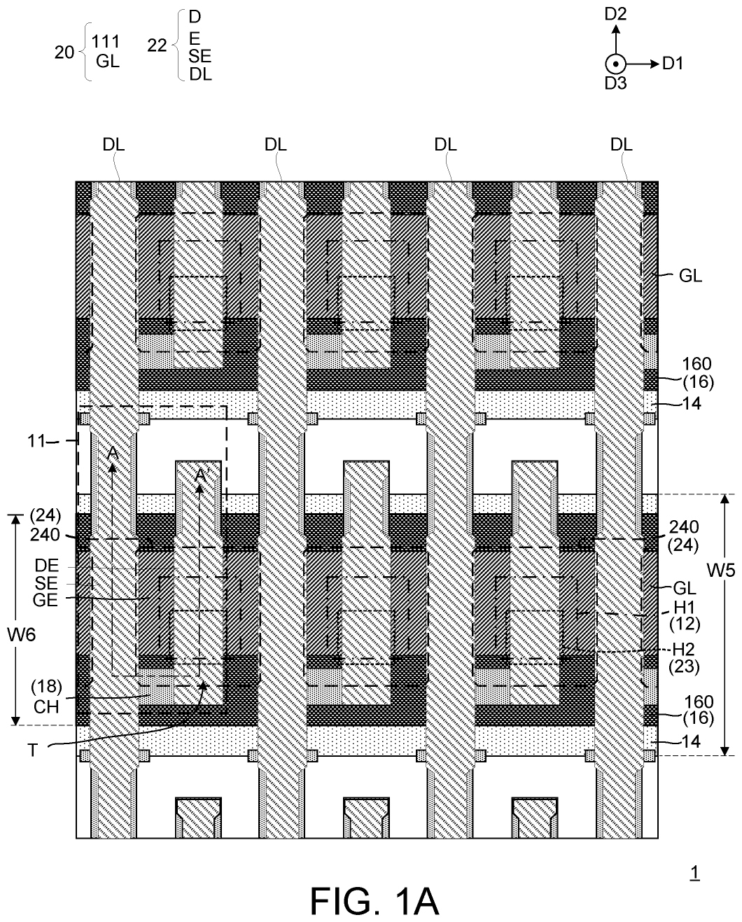

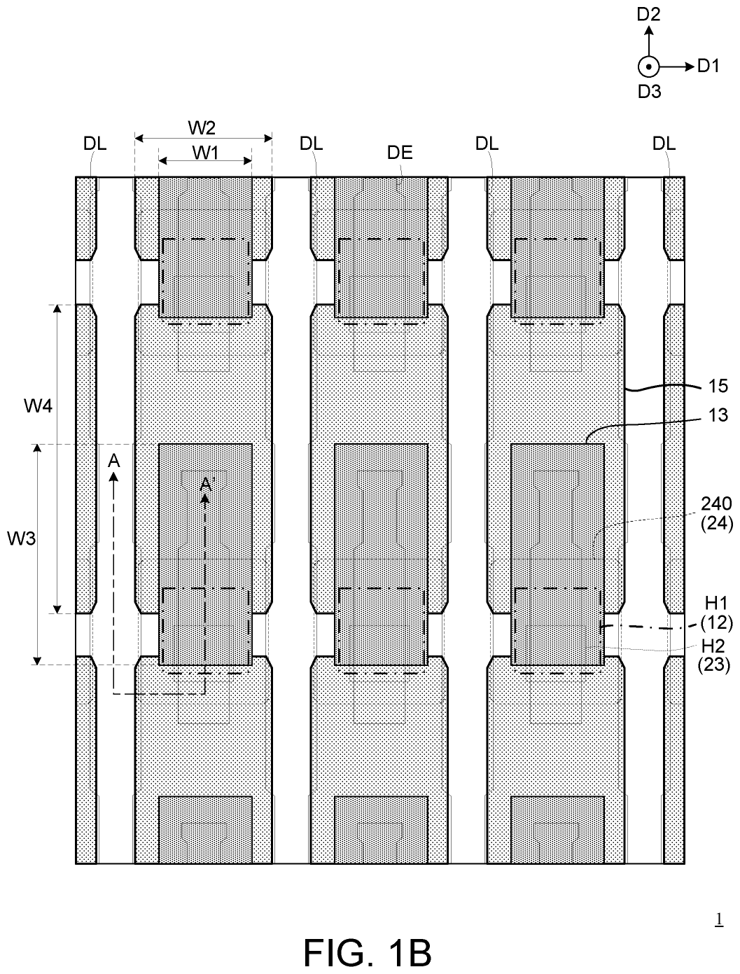

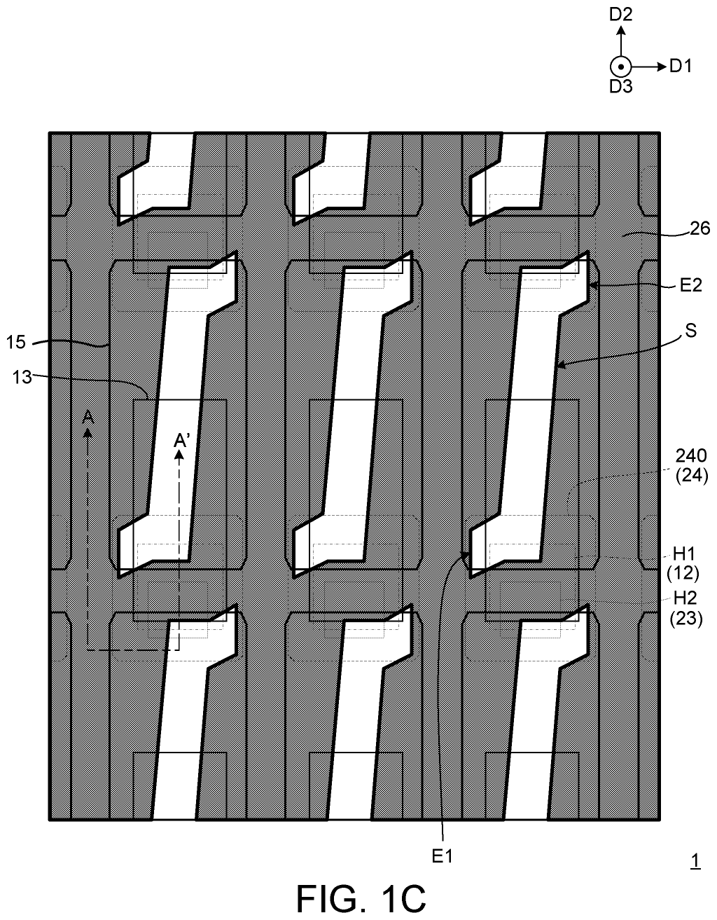

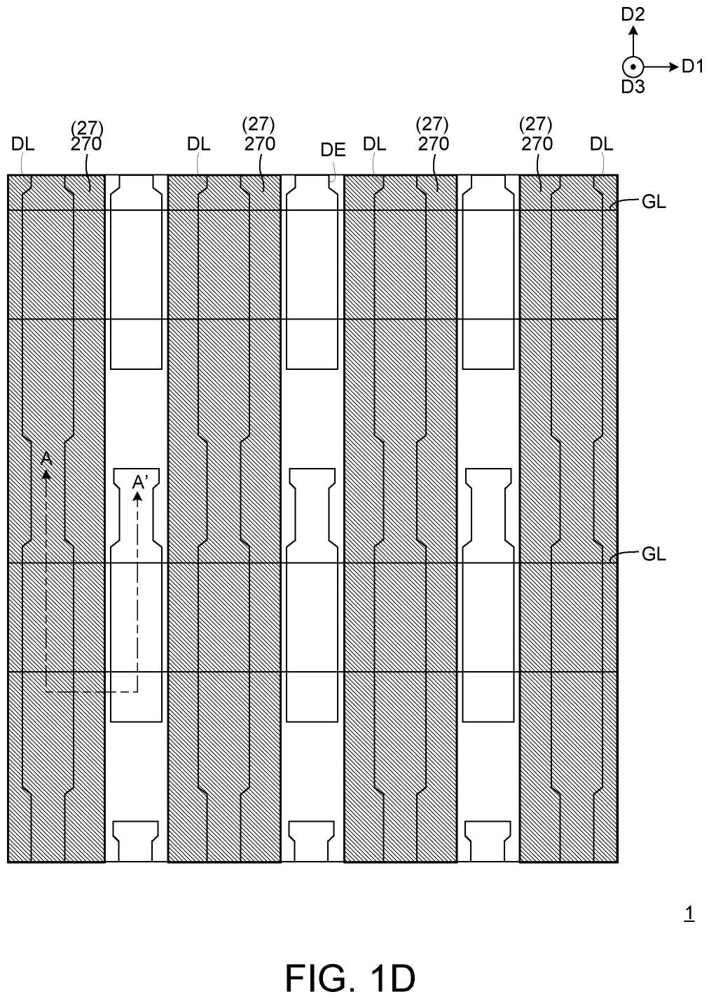

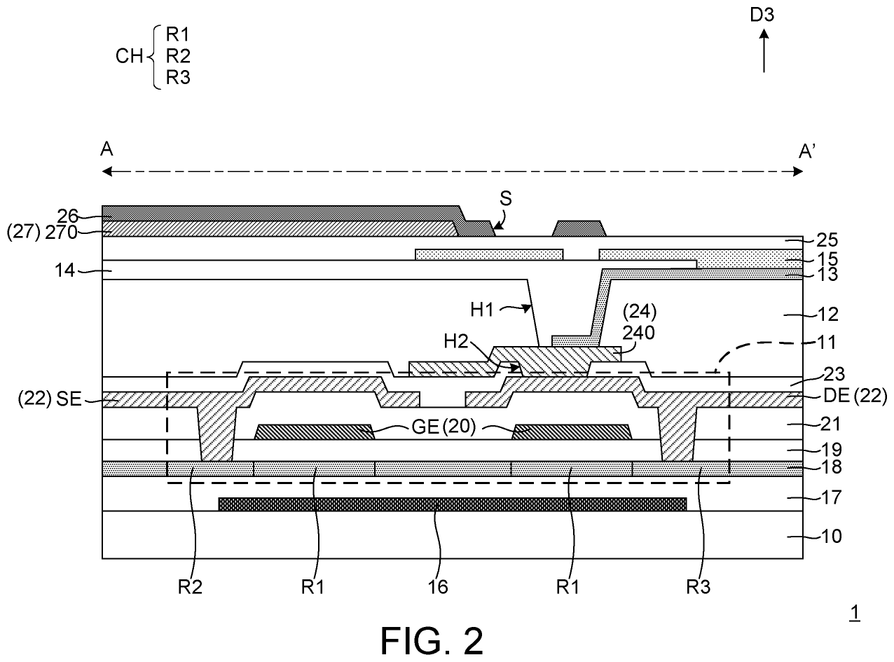

FIG. 1A to FIG. 1D are schematic partial top views of an electronic device according to a first embodiment of the disclosure. FIG. 2 is a schematic cross-sectional view corresponding to a section line A-A′ of FIG. 1A to FIG. 1D. It should be noted that FIG. 1A to FIG. 1D are schematic top views corresponding to the same area of the electronic device. In order to simplify the drawings and/or clearly show the relative disposition relationship of components, multiple schematic top views are used to respectively mark the different components and layers in the area.

Referring to FIG. 2, an electronic device 1 may include a substrate 10, a thin film transistor 11, a first organic layer 12, a first transparent electrode 13, a second organic layer 14, and a second transparent electrode 15. The thin film transistor 11 is disposed on the substrate 10. The first organic layer 12 is disposed on the thin film transistor 11 and has a hole H1. The first transparent electrode 13 is disposed on the first organic layer 12 and is at least partially disposed in the hole H1. The first transparent electrode 13 is electrically connected to the thin film transistor 11 through the hole H1. The second organic layer 14 is disposed on the first transparent electrode 13 and is at least partially disposed in the hole H1. The second transparent electrode 15 is disposed on the second organic layer 14 and is electrically connected to the first transparent electrode 13. As shown in FIG. 1B, the first transparent electrode 13 and the second transparent electrode 15 respectively have a first width W1 and a second width W2 in a first direction D1, and the first width W1 is less than the second width W2.

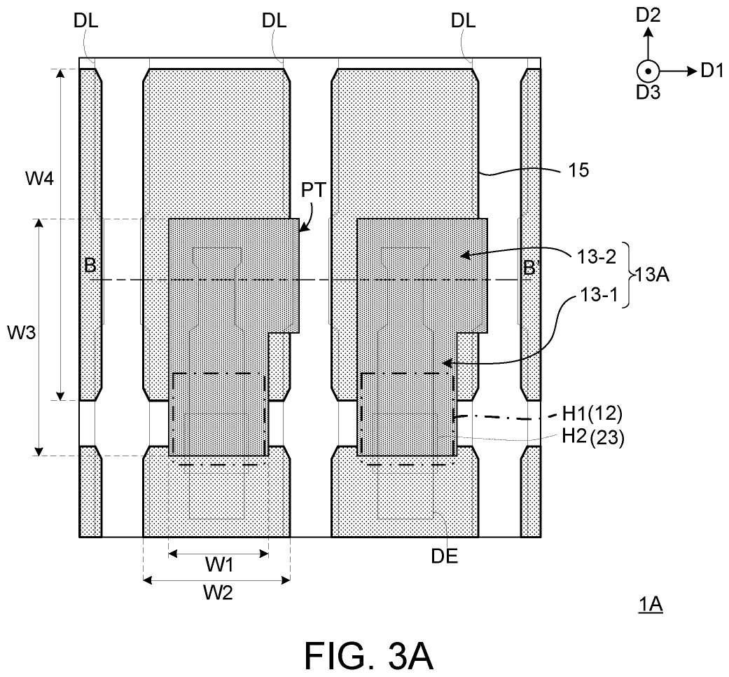

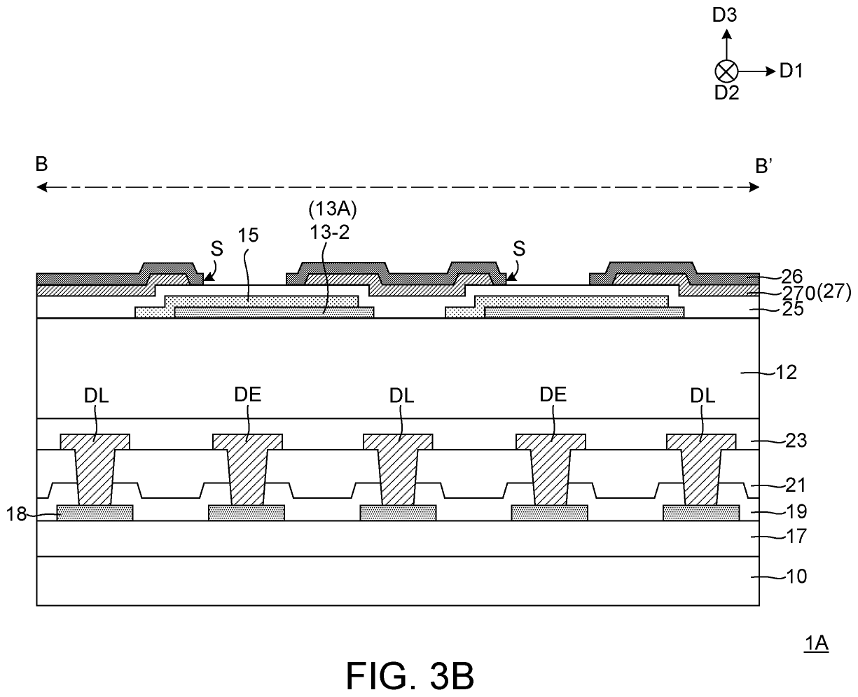

The first width W1 is the maximum width of the first transparent electrode 13 overlapping the hole H1 in the first direction D1 from the top view of the electronic device 1 (for example, FIG. 1B), and the second width W2 is the maximum width of the second transparent electrode 15 in the first direction D1 from the top view of the electronic device 1. Herein, two elements overlapping generally refers to at least a partial overlapping of the two elements in a direction perpendicular to the substrate 10 (e.g., a third direction D3). In other words, the “first transparent electrode 13 overlapping the hole H1” refers to the first transparent electrode 13 at least partially overlapping the hole H1 in a third direction D3. Although FIG. 1B schematically shows that the first transparent electrode 13 has a single width in the first direction D1, the disclosure is not limited thereto. In other embodiments, as shown in FIG. 3A, a first transparent electrode 13A may have different widths in the first direction D1. Under the framework, the first width W1 is the maximum width of the area of the first transparent electrode 13A at least partially overlapping the hole H1 (such as a first portion 13-1 of the first transparent electrode 13A) in the first direction D1.

In detail, as shown in FIG. 2, the substrate 10 may be a rigid substrate or a flexible substrate. The material of the substrate 10 includes, for example, glass, quartz, ceramics, sapphire, or plastic, but the disclosure is not limited thereto. The plastic may include polycarbonate (PC), polyimide (PI), polypropylene (PP), polyethylene terephthalate (PET), and other suitable flexible materials or a combination of the aforementioned materials, but the disclosure is not limited thereto.

The type of the thin film transistor 11 is not limited. For example, the thin film transistor 11 may include a semiconductor pattern CH, a gate electrode GE, a source electrode SE, and a drain electrode DE. The semiconductor pattern CH may include a channel area R1, a source area R2, and a drain area R3, and the channel area R1 is located between the source area R2 and the drain area R3. The gate electrode GE is disposed above the semiconductor pattern CH and overlaps the channel area R1. The source electrode SE and the drain electrode DE are respectively disposed above the source area R2 and the drain area R3 and are electrically connected to the source area R2 and the drain area R3 respectively.

The materials of the first organic layer 12 and the second organic layer 14 include, for example, organic insulating materials, such as polymethyl methacrylate (PMMA), epoxy resin (epoxy), acrylic-based resin, silicone, polyimide polymer, or combinations of the above, but the disclosure is not limited thereto.

The materials of the first transparent electrode 13 and the second transparent electrode 15 include, for example, transparent conduction materials, such as metal oxides, graphene, other suitable transparent conduction materials, or combinations of the above. The metal oxides may include indium tin oxides, indium zinc oxides, aluminum tin oxides, aluminum zinc oxides, indium germanium zinc oxides, or other metal oxides.

According to different requirements, the electronic device 1 may optionally include other elements or film layers. For example, the electronic device 1 may further include a light shielding layer 16. The light shielding layer 16 is disposed on the substrate 10 and is located between the thin film transistor 11 and the substrate 10. The material of the light shielding layer 16 includes, for example, metal, alloy, or other light reflecting materials or light absorbing materials. The light shielding layer 16 overlaps at least the channel area R1 of the semiconductor pattern CH in the third direction D3, so as to reduce the interference of light (such as backlight) on the channel area R1. In some embodiments, as shown in FIG. 1A, the light shielding layer 16 may be a patterned light shielding layer and includes multiple light shielding patterns 160. The multiple light shielding patterns 160, for example, respectively extend along the first direction D1 and are arranged in a second direction D2. The second direction D2 is different from the first direction D1, and the first direction D1 and the second direction D2 intersect each other. For example, the first direction D1 and the second direction D2 are perpendicular to each other, but the disclosure is not limited thereto. In other embodiments, the light shielding layer 16 may be electrically connected to the gate electrode GE of the thin film transistor 11, but the disclosure is not limited thereto.

As shown in FIG. 2, the electronic device 1 may further include an insulation layer 17. The insulation layer 17 is disposed on the substrate 10 and the light shielding layer 16. The material of the insulation layer 17 includes, for example, an inorganic material such as silicon oxide, silicon nitride, or a combination of the above, but the disclosure is not limited thereto.

The electronic device 1 may also include a semiconductor layer 18. The semiconductor layer 18 is disposed on the insulation layer 17. The material of the semiconductor layer 18 includes, for example, amorphous silicon, polysilicon, metal oxide, or a combination of the above, but the disclosure is not limited thereto. The metal oxide includes, for example, indium gallium zinc oxide (IGZO), but the disclosure is not limited thereto. As shown in FIG. 1A, the semiconductor layer 18 is, for example, a patterned semiconductor layer and may include multiple semiconductor patterns CH. The multiple semiconductor patterns CH may be arranged in an array in the first direction D1 and the second direction D2.

As shown in FIG. 2, the electronic device 1 may further include an insulation layer 19. The insulation layer 19 is disposed on the semiconductor layer 18. The material of the insulation layer 19 includes, for example, an inorganic material such as silicon oxide or silicon nitride, but the disclosure is not limited thereto.

The electronic device 1 may further include a conduction layer 20. The conduction layer 20 is disposed on the insulation layer 19, and the material of the conduction layer 20 includes, for example, metal or a metal stack, such as titanium, aluminum, molybdenum, or a combination of the above, but the disclosure is not limited thereto. The conduction layer 20 may be a patterned conduction layer, and the conduction layer 20 may include a gate electrode GE, a gate line GL (see FIG. 1A) and other lines (not shown), but the disclosure is not limited thereto. The gate line GL is disposed on the substrate 10, and as shown in FIG. 1A, the extending direction of the gate line GL may be parallel to the first direction D1. In addition, the conduction layer 20 may include multiple gate lines GL, and the multiple gate lines GL may be arranged in the second direction D2. The gate electrode GE and the gate line GL are electrically connected. In some embodiments, the overlapping area of the gate line GL and the thin film transistor 11 may be used as the gate electrode GE, but the disclosure is not limited thereto.

As shown in FIG. 2, the electronic device 1 may further include an insulation layer 21. The insulation layer 21 is disposed on the insulation layer 19 and the conduction layer 20. The material of the insulation layer 21 includes, for example, an inorganic material such as silicon oxide or silicon nitride, but the disclosure is not limited thereto.

The electronic device 1 may further include a conduction layer 22. The conduction layer 22 is disposed on the insulation layer 21, and the material of the conduction layer 22 includes, for example, metal or a metal stack, such as titanium, aluminum, molybdenum, or a combination of the above, but the disclosure is not limited thereto. The conduction layer 22 may be a patterned conduction layer, and the conduction layer 22 may include the source electrode SE, the drain electrode DE, a data line DL (see FIG. 1A) and other lines (not shown), but the disclosure is not limited thereto. The source electrode SE may penetrate through the insulation layer 19 and the insulation layer 21 to be electrically connected to the source area R2. The drain electrode DE may penetrate through the insulation layer 19 and the insulation layer 21 to be electrically connected to the drain area R3. As shown in FIG. 1A, the extending direction of the data line DL may be parallel to the second direction D2. In addition, the conduction layer 22 may include multiple data lines DL, and the multiple data lines DL may be arranged in the first direction D1. The source electrode SE and the data line DL are electrically connected. In some embodiments, the overlapping area of the data line DL and the thin film transistor 11 may be used as the source electrode SE, but the disclosure is not limited thereto.

As shown in FIG. 2, the electronic device 1 may further include an insulation layer 23. The insulation layer 23 is disposed on the insulation layer 21 and the conduction layer 22. The material of the insulation layer 23 includes, for example, an inorganic material such as silicon oxide or silicon nitride, but the disclosure is not limited thereto. In detail, the insulation layer 23 is, for example, disposed between the thin film transistor 11 and the first organic layer 12 and has a hole H2. The hole H2 overlaps the hole H1 of the first organic layer 12. In other words, the hole H2 and the hole H1 at least partially overlap in the third direction D3, as shown in FIG. 1B or FIG. 1C. The top view shapes of the hole H1 and hole H2 may be changed according to requirements, and are not limited to the quadrangular shapes shown in FIG. 1B and FIG. 1C.

As shown in FIG. 2, the electronic device 1 may further include a conduction layer 24. The conduction layer 24 is disposed on the insulation layer 23. The material of the conduction layer 24 includes, for example, metal or a metal stack, such as titanium, aluminum, molybdenum, or a combination of the above, but the disclosure is not limited thereto. The conduction layer 24 may be a patterned conduction layer, and the conduction layer 24 may include a conduction pattern 240. The conduction pattern 240 is disposed on the insulation layer 23 and in the hole H2. The conduction pattern 240 is electrically connected to the thin film transistor 11 through the hole H2 of the insulation layer 23, and the first transparent electrode 13 is electrically connected to the conduction pattern 240 through the hole H1 of the first organic layer 12. For example, the conduction pattern 240 may be electrically connected to the drain electrode DE of the thin film transistor 11 through the hole H2, and the first transparent electrode 13 may be electrically connected to the conduction pattern 240 through the hole H1. In other words, the first transparent electrode 13 is electrically connected to the drain electrode DE of the thin film transistor 11 through the conduction pattern 240.

As shown in FIG. 1B, the conduction layer 24 may include multiple conduction patterns 240, and the multiple conduction patterns 240 may be arranged in an array in the first direction D1 and the second direction D2. In some embodiments, the conduction pattern 240 may not only be used for signal transfer and/or improving electrical conduction, but also be used for shielding light leakage. For example, from the top view of the electronic device 1, as shown in FIG. 1B, each conduction pattern 240 may at least partially overlap the hole H1 and the hole H2, and the area of the conduction pattern 240 is, for example, greater than the combination of the areas of the corresponding hole H1 and the hole H2, so that the light leakage caused by the poor alignment of liquid crystals may be shielded, but the disclosure is not limited thereto. In other embodiments, although not shown, the conduction layer 24 may also be omitted, and the first transparent electrode 13 may be electrically connected to the drain electrode DE of the thin film transistor 11 through the hole H1 and the hole H2.

As shown in FIG. 2, the first organic layer 12 is disposed on the insulation layer 23 and the conduction layer 24, and the first organic layer 12 may provide a flat surface for disposing the first transparent electrode 13. In some embodiments, as shown in FIG. 1A, the shape of the semiconductor pattern CH is, for example, U-shaped, and the hole H1 of the first organic layer 12 is, for example, disposed adjacent to a turning point T of the U shape. By overlapping the conduction pattern 240 with the drain electrode DE and the hole H1, the penetration rate (or aperture ratio) of the pixel may be improved.

As shown in FIG. 2, the first transparent electrode 13 is disposed on the first organic layer 12, and the first transparent electrode 13 may extend from the top surface of the first organic layer 12 to the bottom of the hole H1 through the sidewall of the hole H1 to be electrically connected with the conduction pattern 240. In some embodiments, as shown in FIG. 2, the end of the first transparent electrode 13 extending into the hole H1 may be located at the bottom of the hole H1, but the disclosure is not limited thereto. In other embodiments, although not shown, the end of the first transparent electrode 13 extending into the hole H1 may further extend upwards to the other sidewall of the hole H1. Alternatively, the end of the first transparent electrode 13 may further extend upwards to the top surface of the first organic layer 12. As shown in FIG. 1B, the electronic device 1 may include multiple first transparent electrodes 13. The multiple first transparent electrodes 13 may extend in the second direction D2, and the multiple first transparent electrodes 13 may be arranged in an array in the first direction D1 and the second direction D2.

As shown in FIG. 2, the second organic layer 14 is disposed on the first organic layer 12 and the first transparent electrode 13. The second organic layer 14, for example, fills the hole H1, and the second organic layer 14, for example, exposes at least part of the first transparent electrode 13 disposed on the first organic layer 12. In some embodiments, as shown in FIG. 1A, the second organic layer 14 may overlap the light shielding layer 16, and the second organic layer 14 may extend along the first direction D1. In some embodiments, a width W5 of the second organic layer 14 in the second direction D2 may be different from a width W6 of the light shielding layer 16 in the second direction D2. For example, when the width W5 is greater than the width W6, the filling effect may be ensured. In some other embodiments, the width W5 may also be less than the width W6, and the light shielding layer 16 may shield the edge of the second organic layer 14 to reduce the possibility of light leakage and improve the display quality.

As shown in FIG. 2, the second transparent electrode 15 is disposed on the first transparent electrode 13 and the second organic layer 14, and the second transparent electrode 15 may be in contact with at least part of the first transparent electrode 13 exposed by the second organic layer 14, and then the second transparent electrode 15 may be electrically connected to the drain electrode DE of the thin film transistor 11 through the first transparent electrode 13 and the conduction pattern 240. In some embodiments, the conduction pattern 240 may not be provided, so the second transparent electrode 15 may be electrically connected to the drain electrode DE of the thin film transistor 11 through the first transparent electrode 13.

As shown in FIG. 1B, the electronic device 1 may include multiple second transparent electrodes 15. The multiple second transparent electrodes 15 may extend in the second direction D2, and the multiple second transparent electrodes 15 may be arranged in an array in the first direction D1 and the second direction D2. In the second direction D2, each first transparent electrode 13 is, for example, disposed between two adjacent second transparent electrodes 15, and the two opposite ends of the first transparent electrode 13 may respectively overlap the two adjacent second transparent electrodes 15, but the disclosure is not limited thereto.

In some embodiments, the first transparent electrode 13 has a third width W3 in the second direction D2, the second transparent electrode 15 has a fourth width W4 in the second direction D2, and the third width W3 is less than the fourth width W4. The third width W3 is the maximum width of the first transparent electrode 13 in the second direction D2 from the top view of the electronic device 1 (for example, FIG. 1B), and the fourth width W4 is the maximum width of the second transparent electrode 15 in the second direction D2 from the top view of the electronic device 1. In some embodiments, the area of the first transparent electrode 13 may be less than the area of the second transparent electrode 15.

As shown in FIG. 2, the electronic device 1 may further include an insulation layer 25. The insulation layer 25 is disposed on the second organic layer 14 and the second transparent electrode 15. The material of the insulation layer 25 includes, for example, an inorganic material such as silicon oxide or silicon nitride, but the disclosure is not limited thereto.

The electronic device 1 may further include a transparent conduction layer 26. The transparent conduction layer 26 is disposed on the insulation layer 25 and has an opening S. From the top view of the electronic device 1, as shown in FIG. C, the end of the opening S (such as an end E1 and an end E2) may be located outside the hole H1 of the first organic layer 12, but the disclosure is not limited thereto. In other embodiments, from the top view of the electronic device 1, the end of the opening S may also end on the hole H1, so that the efficiency of the liquid crystal and the contrast ratio may be improved to increase the display quality. In some embodiments, the second transparent electrode 15 is, for example, a pixel electrode, and the transparent conduction layer 26 is, for example, a common electrode layer, and multiple openings S of the transparent conduction layer 26 and the multiple second transparent electrodes 15, for example, overlap in the direction D3, but the disclosure is not limited thereto.

As shown in FIG. 2, the electronic device 1 may further include a conduction layer 27. The conduction layer 27 is disposed on the insulation layer 25 and is, for example, located between the transparent conduction layer 26 and the insulation layer 25, but the disclosure is not limited thereto. In other embodiments, the conduction layer 27 may also be disposed on the transparent conduction layer 26. For example, the transparent conduction layer 26 is located between the conduction layer 27 and the insulation layer 25, but the disclosure is not limited thereto. The conduction layer 27 may be used, for example, to block the color mixing, reduce the metal reflection, or reduce the impedance of the transparent conduction layer 26. The material of the conduction layer 27 includes, for example, molybdenum or molybdenum oxide, but the disclosure is not limited thereto. The conduction layer 27 may be a patterned conduction layer, and the conduction layer 27 may include a conduction pattern 270. As shown in FIG. 1D, the conduction layer 27 may include multiple conduction patterns 270. The multiple conduction patterns 270 may be arranged in the first direction D1 and respectively extend in the second direction D2. The multiple conduction patterns 270 and the multiple data lines DL are, for example, disposed one-to-one, and each data line DL is, for example, completely covered by a corresponding conduction pattern 270. In other embodiments, the electronic device 1 may also omit the conduction layer 27. In some other embodiments, the conduction layer 27 may also be arranged in the second direction D2 and respectively extend in the first direction D1, but the disclosure is not limited thereto.

Generally speaking, the hole (such as the hole H1) in the organic layer (such as the first organic layer 12) are deep in terrain (the height difference is large). If the pixel electrode, the common electrode, and the insulation layer between the two are formed in the hole of the organic layer, the pixel electrode and the common electrode may be short-circuited due to the poor covering ability and the breakage of the insulation layer in the deep terrain. In addition, the pixel electrode and the common electrode may be short-circuited or open-circuited due to the difference in exposure on the upper and lower sides of the organic layer, and the opening of the common electrode may not be formed as expected due to insufficient exposure at the overlapped hole in the organic layer. In addition, holes deep in the terrain may cause light leakage problems. If, in order to improve the above problems, the thickness of the insulation layer between the pixel electrode and the common electrode is increased, the exposure of the pixel electrode and the common electrode is increased during the lithography process, and/or the area of the light shielding pattern (such as the conduction pattern 240) is increased, the storage capacitance, the penetration rate, and/or the liquid crystal efficiency may be reduced, thereby affecting the display quality.

In the embodiment, by filling the second organic layer 14 into the hole H1 of the first organic layer 12, the second transparent electrode 15, the insulation layer 25, and the transparent conduction layer 26 may be formed above the hole H1, and the second transparent electrode 15 may be electrically connected with the thin film transistor 11 through the first transparent electrode 13. By reducing the layer difference of the second transparent electrode 15, the insulation layer 25, and the transparent conduction layer 26 through the above design, it may improve the aforementioned short circuit caused by the breakage of the insulation layer, and at the same time improve the short circuit or open circuit caused by the difference in exposure of the second transparent electrode 15 and the transparent conduction layer 26 on the upper and lower sides of the first organic layer 12 and/or the decline in the liquid crystal efficiency caused by overexposure. In addition, the decrease in the storage capacitance between the two transparent conduction layers (such as the transparent conduction layer where the second transparent electrode 15 is located and the transparent conduction layer where the transparent conduction layer 26 is located) due to the increase in the thickness of the insulation layer 25 may also be improved. Since the second organic layer 14 is disposed in the hole H1 of the first organic layer 12, the range of light leakage may be reduced, which helps to improve the penetration rate. In addition, compared with metal electrodes, the electrical connection between the second transparent electrode 15 and the thin film transistor 11 through the first transparent electrode 13 also helps to improve the penetration rate (or aperture ratio) of the pixel.

In other embodiments, although not shown, the electronic device 1 may omit the second transparent electrode 15 and use the first transparent electrode 13 as the pixel electrode. Under the framework, it also helps to increase the penetration rate (or aperture ratio) of the pixel. In some embodiments, the electronic device 1 may omit the conduction pattern 240 and the insulation layer 23 in addition to the omitting the second transparent electrode 15, and the first transparent electrode 13 may be electrically connected to the drain electrode DE through the hole H1.

FIG. 3A is a schematic partial top view of an electronic device according to a second embodiment of the disclosure. FIG. 3B is a schematic cross-sectional view corresponding to a section line B-B′ of FIG. 3A. Please refer to FIG. 3A and FIG. 3B. The main differences between an electronic device 1A and the aforementioned electronic device 1 are described as follows. In the electronic device 1A, the first transparent electrode 13A has a first portion 13-1 and a second portion 13-2. The first portion 13-1 extends along the second direction D2, and the second portion 13-2 extends along the first direction D1. In addition, at least a part of the second portion 13-2 (such as a portion PT) is located between the two adjacent second transparent electrodes 15 in the first direction D1. By extending the first transparent electrode 13A to the area where the second transparent electrode 15 is not disposed, it may help to further increase the storage capacitance.

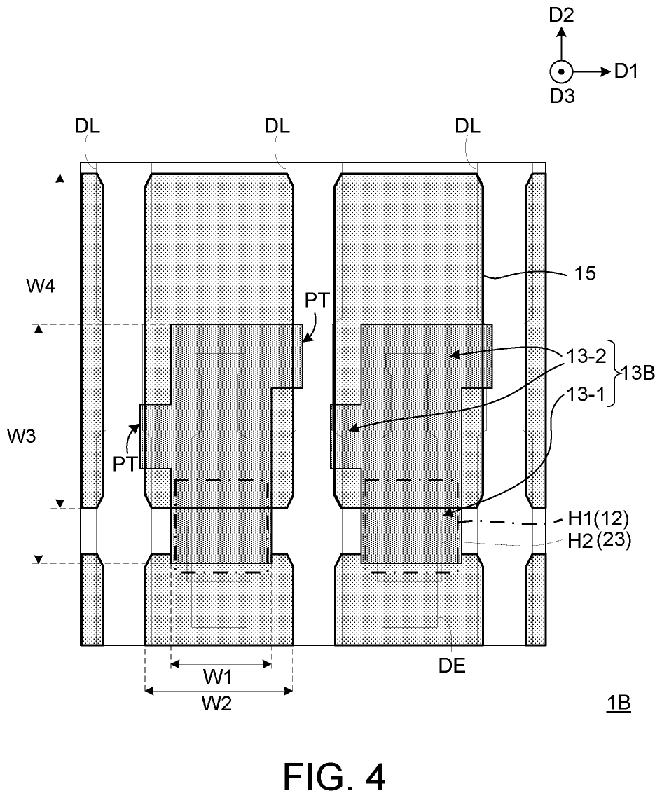

FIG. 4 is a schematic partial top view of an electronic device according to a third embodiment of the disclosure. Please refer to FIG. 4. The main differences between an electronic device 1B and the electronic device 1A of FIG. 3A are described as follows. In the electronic device 1B, a first transparent electrode 13B has two second portions 13-2. One of the second portions 13-2 is located between the other second portion 13-2 and the first portion 13-1, and from the top view of the electronic device 1B, the two second portions 13-2, for example, respectively protrude from two long sides of the second transparent electrode 15. Through the design, it may help to further increase the storage capacitance.

It should be understood that the respective quantity, shape, and relative disposition relationship of the first portion 13-1 and the second portion 13-2 may be changed according to requirements, and are not limited to those shown in FIG. 3A and FIG. 4. In the embodiment of the disclosure, the four corners of the first transparent electrode 13B may be non-right angles, such as in the shape of rounded corners or arcs, but the disclosure is not limited thereto.

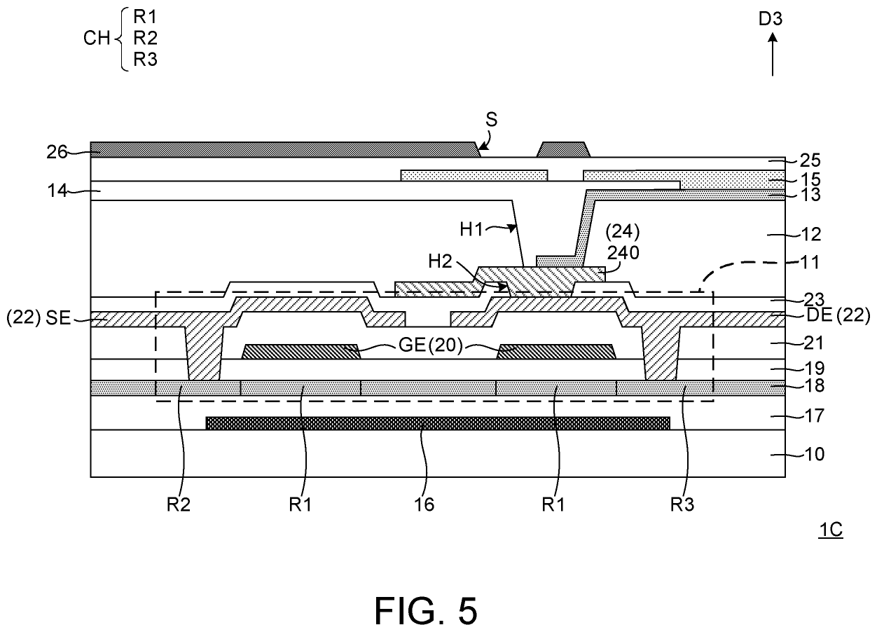

FIG. 5 is a schematic partial cross-sectional view of an electronic device according to a fourth embodiment of the disclosure. Please refer to FIG. 5. The main difference between an electronic device 1C and the electronic device 1 of FIG. 2 is that the electronic device 1C omits the conduction layer 27.

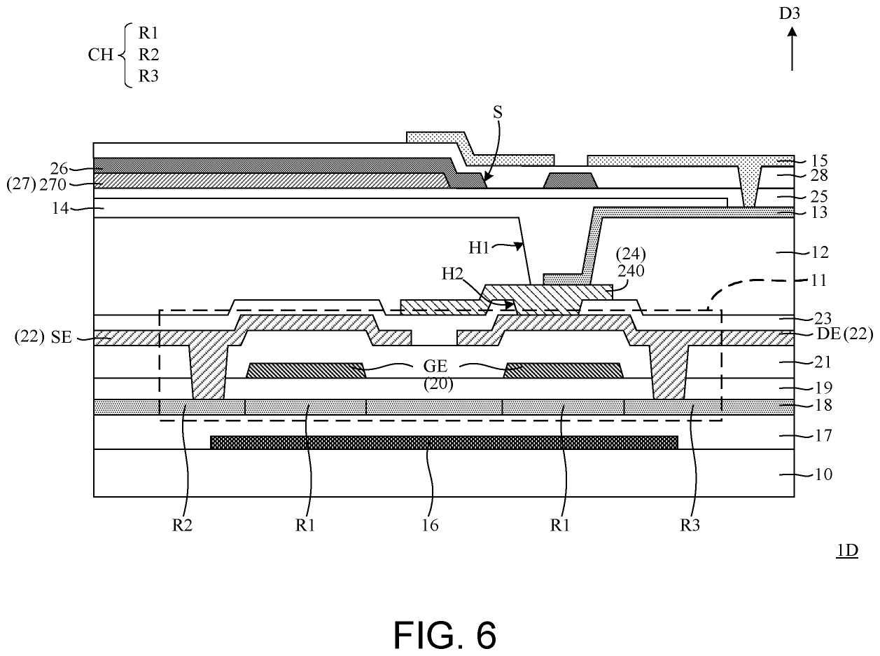

FIG. 6 is a schematic partial cross-sectional view of an electronic device according to a fifth embodiment of the disclosure. Please refer to FIG. 6. The main difference between an electronic device 1D and the electronic device 1 of FIG. 2 is that the conduction layer 27 and the transparent conduction layer 26 are disposed between the second transparent electrode 15 and the substrate 10. Specifically, in the electronic device 1D, the insulation layer 25 is disposed on the first transparent electrode 13 and the second organic layer 14. The electronic device 1D also includes an insulation layer 28. The insulation layer 28 is disposed on the transparent conduction layer 26 and the insulation layer 25. The material of the insulation layer 28 includes, for example, an inorganic material such as silicon oxide or silicon nitride, but the disclosure is not limited thereto. The second transparent electrode 15 is disposed on the insulation layer 28, and the second transparent electrode 15 penetrates through the insulation layer 28 and the insulation layer 25 to be electrically connected to the first transparent electrode 13.

To sum up, in the embodiment of the disclosure, the second transparent electrode and the thin film transistor are electrically connected through the first transparent electrode, and the second organic layer is disposed on the first transparent electrode and is at least partially disposed in the hole of the first organic layer. The second transparent electrode may be formed above the hole, so the short circuit or open circuit and/or the decline in the liquid crystal efficiency caused by overexposure may be improved. In addition, the electrical connection between the second transparent electrode and the thin film transistor through the first transparent electrode also helps to improve the penetration rate (or aperture ratio) of the pixel. Therefore, the electronic device of the disclosure helps to improve display quality.

The above embodiments are only used to illustrate, but not to limit, the technical solution of the disclosure. Although the disclosure has been described in detail with reference to the above embodiments, persons skilled in the art should understand that the technical solutions described in the above embodiments may still be modified or some or all of the technical features thereof may be equivalently replaced. However, these modifications or replacements do not cause the essence of the corresponding technical solutions depart from the scope of the technical solutions of the embodiments of the disclosure.

Although the embodiments of the disclosure and the advantages thereof have been disclosed above, it should be understood that any person skilled in the art may make changes, substitutions, and modifications without departing from the spirit and scope of the disclosure, and the features of each embodiment may be arbitrarily mixed and replaced with each other to form other new embodiments. In addition, the protection scope of the disclosure is not limited to the processes, machines, manufactures, material compositions, devices, methods, and steps in the specific embodiments described in the specification, and any person skilled in the art may learn from the content of the disclosure the current or future developed processes, machines, manufactures, material compositions, devices, methods, and steps which may be used according to the disclosure as long as they may perform substantially the same function or obtain substantially the same results in the embodiments described herein. Therefore, the protection scope of the disclosure includes the above processes, machines, manufactures, material compositions, devices, methods, and steps. In addition, each claim constitutes an individual embodiment, and the protection scope of the disclosure also includes combinations of the individual claims and the embodiments. The protection scope of the disclosure shall be defined by the appended claims.

What is claimed is:

1. An electronic device, comprising:
a substrate;
a thin film transistor, disposed on the substrate;
a first organic layer, disposed on the thin film transistor, and having a hole;
a first transparent electrode, disposed on the first organic layer, and being at least partially disposed in the hole, wherein the first transparent electrode is electrically connected to the thin film transistor through the hole;
a second organic layer, disposed on the first transparent electrode, and being at least partially disposed in the hole; and
a second transparent electrode, disposed on the second organic layer, and electrically connected to the first transparent electrode,
wherein the first transparent electrode has a first width in a first direction, the second transparent electrode has a second width in the first direction, and the first width is less than the second width.

2. The electronic device according to claim 1, wherein the first transparent electrode has a third width and the second transparent electrode has a fourth width in a second direction, the second direction is different from the first direction, and the third width is less than the fourth width.

3. The electronic device according to claim 1, wherein an area of the first transparent electrode is less than an area of the second transparent electrode.

4. The electronic device according to claim 1, wherein the first transparent electrode has a first portion and a second portion, the first portion extends along a second direction, the second portion extends along the first direction, and the second direction is different from the first direction.

5. The electronic device according to claim 4, further comprising:
a gate line, disposed on the substrate, wherein an extending direction of the gate line is parallel to the first direction.

6. The electronic device according to claim 5, wherein the electronic device comprises a plurality of second transparent electrodes, the plurality of second transparent electrodes are arranged in the first direction, and at least a part of the second portion is located between two adjacent second transparent electrodes in the first direction.

7. The electronic device according to claim 1, wherein the second organic layer extends along the first direction.

8. The electronic device according to claim 1, further comprising:
an insulation layer, disposed between the thin film transistor and the first organic layer, and having a hole; and
a conduction pattern, disposed on the insulation layer and in the hole of the insulation layer, wherein the first transparent electrode is electrically connected to the thin film transistor through the conduction pattern.

9. The electronic device according to claim 8, wherein the hole of the insulation layer overlaps the hole of the first organic layer.

10. The electronic device according to claim 1, further comprising:
an insulation layer, disposed on the second organic layer and the second transparent electrode; and
a transparent conduction layer, disposed on the insulation layer, and having an opening, wherein an end of the opening is located outside the hole of the first organic layer from a top view of the electronic device.

11. The electronic device according to claim 1, further comprising:
a light shielding layer, disposed on the substrate and located between the thin film transistor and the substrate, wherein an extending direction of the light shielding layer is parallel to the first direction.

12. The electronic device according to claim 11, wherein the second organic layer overlaps the light shielding layer.

13. The electronic device according to claim 12, wherein a width of the second organic layer in a second direction is different from a width of the light shielding layer in a second direction, and the second direction is perpendicular to in the first direction.

14. The electronic device according to claim 1, further comprising:
a plurality of data lines, disposed on the substrate, wherein extending directions of the plurality of data lines are parallel to a second direction, and the second direction is different from the first direction;
an insulation layer, disposed on the second organic layer and the second transparent electrode; and
a conduction layer, disposed on the insulation layer, and comprising a plurality of conduction patterns, wherein the plurality of conduction patterns and the plurality of data lines overlap.

15. The electronic device according to claim 14, wherein the plurality of conduction patterns and the plurality of data lines are disposed one-to-one, and each of the plurality of data lines is completely covered by a corresponding conduction pattern.

16. The electronic device according to claim 14, further comprising:
a transparent conduction layer, disposed on the insulation layer and the conduction layer, and having an opening, wherein an end of the opening is located outside the hole of the first organic layer from a top view of the electronic device.

17. The electronic device according to claim 1, further comprising:
a first insulation layer, disposed on the second organic layer and the first transparent electrode;
a transparent conduction layer, disposed on the first insulation layer; and
a second insulation layer, disposed on the transparent conduction layer and the first insulation layer, wherein the second transparent electrode is disposed on the second insulation layer, and the second transparent electrode penetrates through the first insulation layer and the second insulation layer to be electrically connected to the first transparent electrode.

18. The electronic device according to claim 17, further comprising:
a conduction layer, disposed on the first insulation layer, and being located between the transparent conduction layer and the first insulation layer, wherein an impedance of the conduction layer is lower than an impedance of the transparent conduction layer.

19. The electronic device according to claim 17, wherein the transparent conduction layer has an opening, and an end of the opening is located outside the hole of the first organic layer from a top view of the electronic device.

20. The electronic device according to claim 19, wherein the second transparent electrode is a pixel electrode, the transparent conduction layer is a common electrode layer, and the opening of the transparent conduction layer and the second transparent electrode overlap.
